(19) United States
(12) Patent Application Publication
(10) Pub. No.: US 2024/0128197 A1
(43) Pub. Date: Apr. 18, 2024

(54) ASSEMBLIES WITH EMBEDDED SEMICONDUCTOR DEVICE MODULES AND RELATED METHODS

(71) Applicant: SEMICONDUCTOR COMPONENTS INDUSTRIES, LLC, Scottsdale, AZ (US)

(72) Inventors: Olaf ZSCHIESCHANG, Sinsheim (DE); Oseob JEON, Seoul (KR); Jihwan KIM, Seoul (KR); Roveendra PAUL, Dublin, CA (US); Klaus NEUMAIER, Erding (DE); Jerome TEYSSEYRE, Singapore (SG)

(73) Assignee: SEMICONDUCTOR COMPONENTS INDUSTRIES, LLC, Scottsdale, AZ (US)

(21) Appl. No.: 18/487,835

(22) Filed: Oct. 16, 2023

Related U.S. Application Data
(60) Provisional application No. 63/379,853, filed on Oct. 17, 2022.

(51) Int. Cl. H01L 23/538; H01L 21/56; H01L 23/00

(52) U.S. Cl. CPC H01L 23/5389; H01L 21/56; H01L 24/24; H01L 24/82; H01L 25/072

(57) ABSTRACT

In a general aspect, an assembly includes a panel of organic substrate core material having a cavity defined therein, a module substrate disposed in the cavity, and a semiconductor die disposed on the module substrate. The assembly also includes a layer of prepreg organic substrate material, and a metal layer. The module substrate and the semiconductor die are embedded in the cavity by the layer of prepreg organic substrate material and the metal layer. The metal layer is electrically coupled with at least one of the semiconductor die or the module substrate.

### CROSS REFERENCE TO RELATED APPLICATION

This application claims priority to and the benefit of U.S. Provisional Application No. 63/379,853, filed Oct. 17, 2022, which is incorporated herein by reference in its entirety.

### TECHNICAL FIELD

This description relates to semiconductor device assemblies and associated methods of producing such assemblies.

### BACKGROUND

In many semiconductor device assemblies, semiconductor device die are situated on a substrate, a leadframe is coupled with the substrate and a transfer molding process is performed to encapsulate at least portions of the assembly. Such as assembly can then be integrated into a corresponding system. There is, however, increasing demand for improvements in integration of semiconductor device assemblies in related systems, as well as reduction in overall costs of such assemblies, without sacrificing electrical and/or thermal performance.

### SUMMARY

In a general aspect, an assembly includes a panel of organic substrate core material having a cavity defined therein, a module substrate disposed in the cavity, and a semiconductor die disposed on the module substrate. The assembly also includes a layer of prepreg organic substrate material, and a metal layer. The module substrate and the semiconductor die are embedded in the cavity by the layer of prepreg organic substrate material and the metal layer. The metal layer is electrically coupled with at least one of the semiconductor die or the module substrate.

In another general aspect, an assembly includes a panel of organic substrate core material having a first cavity and a second cavity defined therein, a first module substrate disposed in the first cavity, a first semiconductor die disposed on the first module substrate, a second module substrate disposed in the second cavity, a second semiconductor die disposed on the second module substrate, a first layer of prepreg organic substrate material, a first metal layer, a second layer of prepreg organic substrate material, and a second metal layer. The first module substrate, the first semiconductor die, the second module substrate and the second semiconductor die are embedded, respectively, in the first cavity and the second cavity by the first layer of prepreg organic substrate material, the first metal layer, the second layer of prepreg organic substrate material, and the second metal layer.

In another general aspect, a method for producing a semiconductor device assembly includes disposing a module substrate in a cavity defined in a panel of organic substrate core material, and coupling a semiconductor die with the module substrate. The method further includes embedding the module substrate and the semiconductor die by laminating, with a layer of prepreg organic substrate material, the panel of organic substrate core material, the module substrate and the semiconductor die. The method also includes forming a plurality of via openings through the layer of prepreg organic substrate material, and forming a patterned metal layer on the layer of prepreg organic substrate material. The patterned metal layer electrically contacts the module substrate and semiconductor die through the plurality of via openings.

### BRIEF DESCRIPTION OF THE DRAWINGS

FIG. 1 is a block diagram schematically illustrating an example semiconductor device assembly.

FIGS. 2A and 2B are diagrams illustrating respective side cross-sectional views of example semiconductor device assemblies.

FIGS. 3A through 3G are diagrams illustrating an example process for producing a semiconductor device assembly.

FIGS. 4A and 4B are diagrams schematically illustrating an example of semiconductor device assemblies coupled with a heatsink or cooling jacket.

FIG. 5A is a diagram illustrating an example of another semiconductor device assembly.

FIG. 5B is a diagram illustrating an example signal pin of the semiconductor device assembly of FIG. 5A.

FIG. 5C is a diagram illustrating an example panel including a plurality of the semiconductor device assemblies of FIG. 5A.

FIG. 6 is diagram illustrating an example of yet another semiconductor device assembly.

FIG. 7 is a flowchart illustrating an example method for producing a semiconductor device assembly.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of that element are illustrated.

### DETAILED DESCRIPTION

For modern electronic circuits, a plurality of semiconductor die (e.g., metal-oxide-semiconductor field-effect transistors (MOSFET), insulated-gate bipolar transistors (IGBTs), high-side and low-side FET switches of a half-bridge circuit, driver and/or controller IC chips, etc.) may be included in a single device package or assembly. In some prior implementations, a semiconductor device assembly is constructed using a module substrate on which one more semiconductor die are disposed, a leadframe, conductive clips and wire bonds, and an epoxy molding compound (e.g., applied using a transfer molding process). In such implementations, the conductive clips and wire bonds can provide electrical interconnections between the leadframe, the module substrate and/or the semiconductor die. Use of such approaches, e.g., transfer molded modules including leadframes, can limit opportunities for size reduction of an associated semiconductor device module or semiconductor device assembly, as well as limit opportunities to reduce product costs.

The approaches described herein are directed to semiconductor device assemblies that include semiconductor device modules that are embedded in organic substrate material. For instance, in some implementation, the organic substrate material can be a combination of core printed circuit board (PCB) material and resin pre-impregnated PCB material, referred to herein as prepreg PCB material (or prepreg material, or prepreg). For instance, organic substrate materials can include any number of materials, such as FR-4, FR-5, among other materials. The particular material used will depend on the specific implementation, such as on operating temperature. For purposes of this disclosure, such organic substrate materials, e.g., core and prepreg materials, are generally referred to as PCB materials.

Prepreg material, e.g., in combination with metallization, can be used, in the approaches and devices described herein, to laminate and embed semiconductor die (e.g., semiconductor die disposed on one or more module substrates) in respective cavities defined in core PCB material, e.g., using resin flow and cure processes performed at high temperature and pressure. The disclosed approaches and devices can eliminate the use of a leadframe and/or a transfer molding operation. Accordingly, implementations described herein can overcome the size reduction and/or cost reduction limitations of prior approaches. Further, the semiconductor device assembly implementations described herein can have equivalent, or improved thermal performance, as compared to prior implementations, as well as improved electrical performance (e.g., switching performance) due to reduced parasitic inductance as compared to prior implementations.

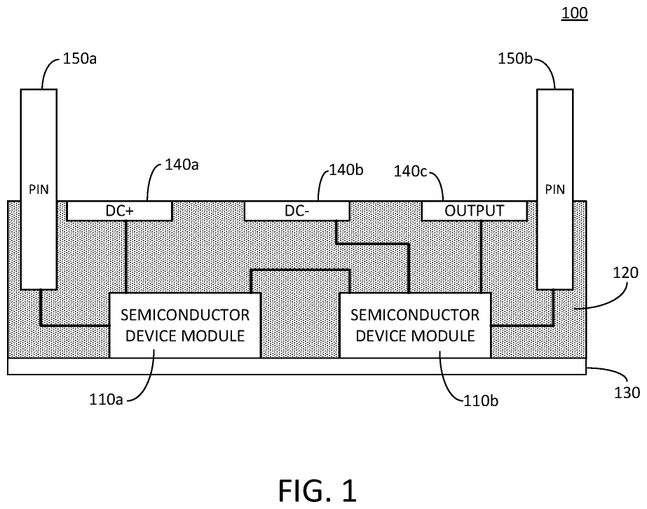

FIG. 1 is a block diagram schematically illustrating an example semiconductor device assembly 100, e.g., in a side view, or side, cross-sectional view. As shown in FIG. 1, the semiconductor device assembly 100 includes a semiconductor device module 110a and a semiconductor device module 110b. In some implementations, the semiconductor device module 110a and the semiconductor device module 110b can each include a module substrate, such as a direct-bonded copper (DBC) substrate, or an active metal-brazed (AMB) substrate. For instance, in such substrates, metal layers can be laminated, diffusion bonded and/or brazed to a surface, or multiple surfaces of a ceramic insulating layer. The metal layers can be patterned or unpatterned. Depending on the particular implementation, a patterned metal layer can be patterned prior to attachment to the ceramic layer, or can be patterned after attachment to the ceramic layer. The ceramic layer provides electrical isolation between metals layers on opposite surfaces (sides, etc.) of the ceramic layer.

As shown in FIG. 1, the semiconductor device module 110a and the semiconductor device module 110b are embedded in PCB material 120. In some implementations, the PCB material 120 can include a combination of core PCB material and prepreg material. The semiconductor device assembly 100 also includes metallization that can be used to defined PCB conductive traces and vias for interconnecting semiconductor die and module substrates of the semiconductor device assembly 100. For instance, in this example, such metallization can define a DC+ terminal 140a, a DC− terminal 140b, and an output terminal 140c of the semiconductor device assembly 100. In this example, the semiconductor device assembly 100 can include a half-bridge circuit, where the output terminal 140c is a switch node of the half-bridge circuit. In some implementations, such metallization can be implemented one or more metal layers, one or more prepreg material layers, and associated conductive vias formed though one more layers of prepreg materials.

The semiconductor device assembly 100 further includes a signal pin 150a and a signal pin 150b, which are electrically coupled, respectively, with the semiconductor device module 110a and the semiconductor device module 110b (e.g., with semiconductor die include in the modules). The signal pin 150a and the signal pin 150b are shown by way of example and for purposes of illustration. In some implementations, a semiconductor device assembly can include additional, or fewer signal pins.

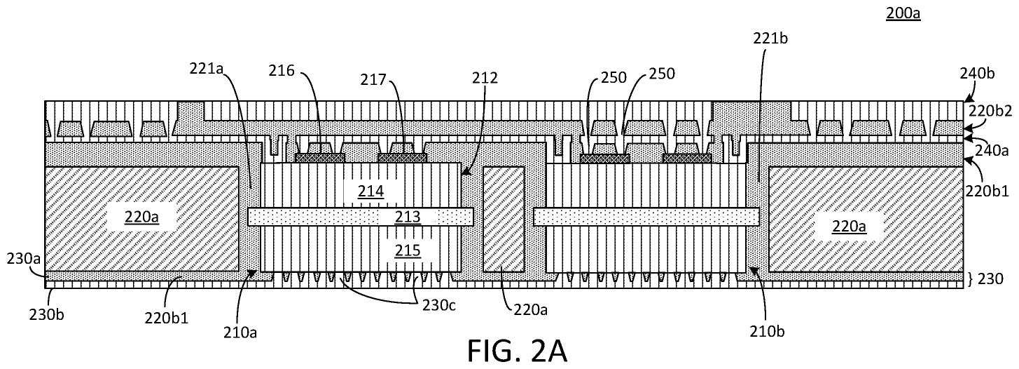

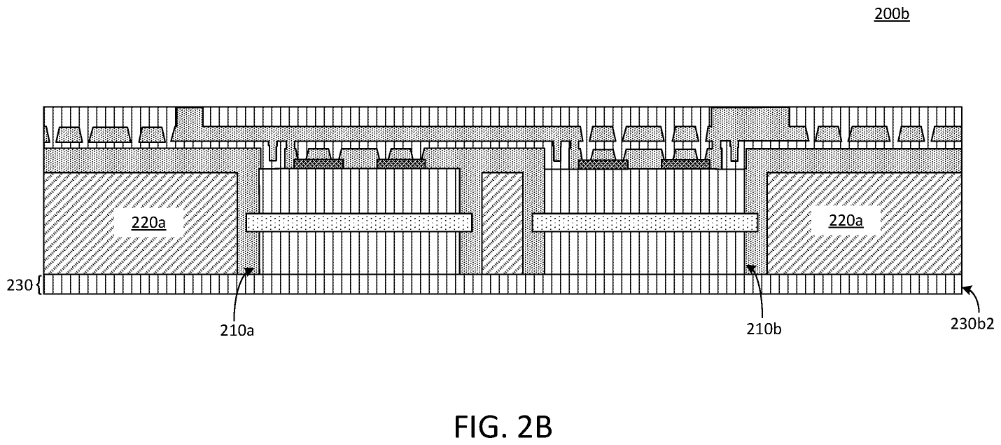

As shown in FIG. 1, the semiconductor device assembly 100 also includes a bottom side layer 130. In some implementations (e.g., the example of FIG. 2B), the bottom side layer 130 can include a metal layer that is disposed on the PCB material 120, the semiconductor device module 110a and the semiconductor device module 110b. That is, in some implementations, the bottom side layer 130 can include a metal layer that is directly disposed on the PCB material 120, the semiconductor device module 110a and the semiconductor device module 110b.

In some implementations (e.g., the example of FIG. 2A), the bottom side layer 130 can include a layer of prepreg material that is disposed on (e.g., disposed directly on) the PCB material 120, the semiconductor device module 110a, and the semiconductor device module 110b. Further in this example, the bottom side layer 130 can include a metal layer that is disposed on the layer of prepreg material of the bottom side layer 130. The metal layer of the bottom side layer 130 can be thermally (and electrically) coupled with respective metals layers of the semiconductor device module 110a and the semiconductor device module 110b using conductive vias (metal filled openings) defined in (through) the prepreg layer of the bottom side layer 130. In some implementations, the bottom side layer 130 can included other materials and/or can have other arrangements.

FIGS. 2A and 2B are diagrams illustrating respective side cross-sectional views of an example semiconductor device assembly 200a (FIG. 2A) and another example semiconductor device assembly 200b. In these examples, the semiconductor device assembly 200a and the semiconductor device assembly 200b include like structures, with the exception of their back side layers. Accordingly, for purposes of brevity, only the differences in the back side layers are described with respect to FIG. 2B, with other details of the semiconductor device assembly 200b discussed with respect to the semiconductor device assembly 200a of FIG. 2A not being repeated in the discussion of FIG. 2B. However, the details of the semiconductor device assembly 200a (other than with respect to its back side layer) apply equally to the semiconductor device assembly 200b.

As shown in FIG. 2A, the semiconductor device assembly 200a includes PCB core material 220a that has a cavity 221a and a cavity 221b defined therein (therethrough, etc.). A back side layer 230 of the semiconductor device assembly 200a can define respective bottom surfaces of the cavities 221a and the cavities 221b. In the semiconductor device assembly 200a, a semiconductor device module 210a is disposed in the cavity 221a, while a semiconductor device module 210b is disposed in the cavity 221b. As the semiconductor device module 210b in this example is similar to the semiconductor device module 210a, for purposes of brevity, only details of the semiconductor device module 210a are described here, and are not repeated with respect to the semiconductor device module 210b.

As shown in FIG. 2A, the semiconductor device module 210a includes a module substrate 212, which can, e.g., be a DBC substrate or an AMB substrate. The module substrate 212 includes a dielectric layer 213 (a ceramic layer, an insulator layer, etc.), a metal layer 214 disposed on a first side of the dielectric layer 213 and a metal layer 215 disposed on a second, opposite side, of the dielectric layer 213. In this example, the metal layer 214 can be a patterned metal layer, while the metal layer 215 can be an unpatterned metal layer to achieve efficient thermal dissipation from the semiconductor device module 210a to the back side layer 230 (and from the semiconductor device module 210b to the back side layer 230).

In this example, the semiconductor device assembly 200a implements a half-bridge circuit, and the semiconductor device module 210a includes a semiconductor die 216 and a semiconductor die 217, which can include respective high-side transistors of the half-bridge circuit that are coupled in parallel with each other. Further, while not specifically reference in FIG. 2A, the semiconductor device module 210b can include two semiconductor die, which can include respective low side transistors of the half-bridge circuit that can be coupled in parallel with each other.

In the example of FIG. 2A, a layer of prepreg 220b1 can be applied to the semiconductor device assembly 200a after attaching the semiconductor die to the module substrates of the semiconductor device assembly 200a. A resin flow process can then be performed to laminated the 220b1, along with a metal foil 240a (e.g. a copper foil layer) to the semiconductor device assembly 200a. The resin flow process can be performed at high temperature and high pressure, which can cause the prepreg material to flow between the PCB core material 220a and the module substrates (e.g., the module substrate 212). That is, the resin flow process can embed the semiconductor device module 210a and the semiconductor device module 210b in their respective cavities 221a and 221b, the prepreg material layer 22b1, and/or the metal foil 240a such as illustrated in FIG. 2A. In an example implementation, resin flow operations can be performed at approximately 200° Celsius (C.) and approximately 200 newtons per centimeter-squared (N/cm²).

Vias openings 250 are defined through the metal foil 240a and the prepreg layer 220b1 for facilitating electric contact to the module substrates (e.g., to the metal layer 214) and the semiconductor die (e.g., the semiconductor die 216 and the semiconductor die 217). The semiconductor device assembly 200a includes additional prepreg material layers, such as a prepreg material layer 220b2 (with additional via openings 250 defined therethrough) and additional metal layers, such a metal layer 240b, which can provide electrical connections to portions of the metal foil 240a, as appropriate for the half-bridge circuit of the semiconductor device assembly 200a. Of course, in some implementations, additional or fewer prepreg material layers and/or metal layers (metal foil layers) can be included in a semiconductor device assembly having embedded semiconductor device modules.

As shown in FIG. 2A, the back side layer 230 includes a prepreg material layer 230a. The back side layer 230 further includes a metal layer 230b that is disposed on the prepreg material layer 230a. As shown in FIG. 2A, the prepreg material layer 230a has openings 230c defined therein, such that portions of the metal layer 230b are disposed in the openings, and in contact with the semiconductor device module 210a and the semiconductor device module 210b, e.g., with the metal layer 215 of the module substrate 212, which can facilitate efficient thermal dissipation for heat generate during operation of the semiconductor device assembly 200a.

Referring now to FIG. 2B, as compared to the back side layer 230 of the semiconductor device assembly 200a, the back side layer 230 of the semiconductor device assembly 200b includes a metal layer 230b2 that is disposed on the PCB core material 220a, and on the back side (bottom side) of the module substates of the semiconductor device module 210a and the semiconductor device module 210b. That is, the metal layer 230b2, in this example, is directly disposed on the PCB core material 220a, on the semiconductor device module 210a, and on the semiconductor device module 210b, e.g., on a back side (bottom side) of the semiconductor device assembly 200b (e.g., in the arrangement of the view shown in FIG. 2B). In some implementations, the respective back side layers 230 of the semiconductor device assembly 200a (FIG. 2A) and the semiconductor device assembly 200b (FIG. 2B) can be formed after forming the PCB laminated layers on the respective top surfaces of the semiconductor device assembly 200a and the semiconductor device assembly 200b (in the arrangement of the views of FIGS. 2A and 2B). In other implementations, the top side and back side layers of the semiconductor device assembly 200a and the semiconductor device assembly 200b can be formed in other orders, or can be formed contemporaneously.

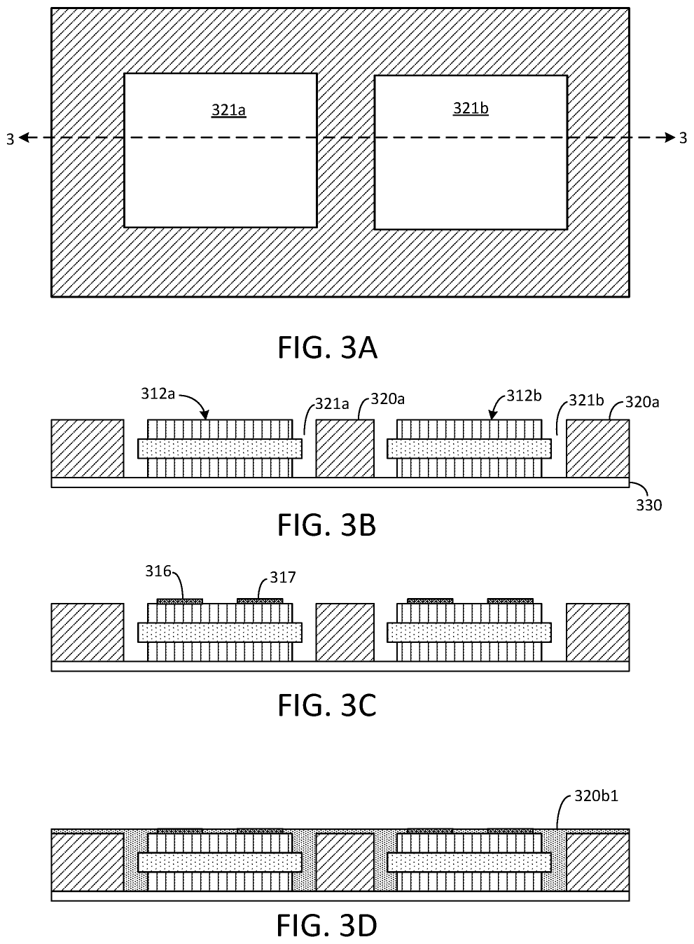

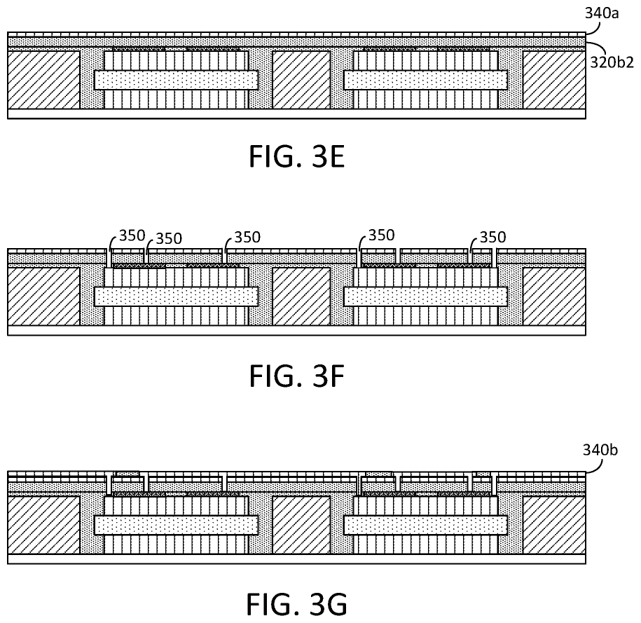

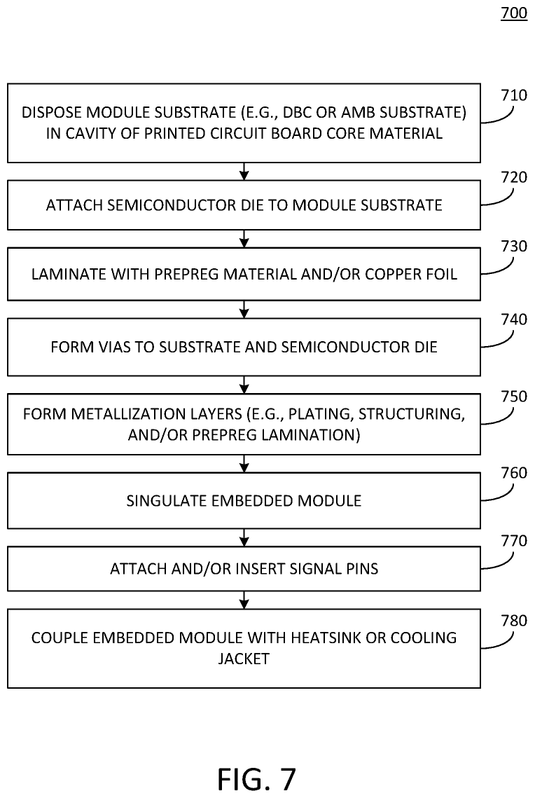

FIGS. 3A through 3G are diagrams illustrating an example process for producing a semiconductor device assembly with embedded semiconductor device modules, such as the semiconductor device assembly 200a of FIG. 2B or the semiconductor device assembly 200b of FIG. 2B. While the process of FIGS. 3A through 3G is illustrated and described as producing a specific semiconductor assembly, such as the semiconductor device assembly 200a or the semiconductor device assembly 200b, in some implementations, the process of FIGS. 3A through 3G (as well as the method of FIG. 7) can be used to produce other semiconductor assemblies, e.g., semiconductor assemblies implementing other circuits, having different arrangements, etc.

As shown in FIG. 3A, a cavity 321a and a cavity 321b are defined in a panel of PCB core material 320a. The section line 3-3 in FIG. 3A corresponds with the cross-sectional views of FIGS. 3B to 3G (as well as the views of FIGS. 1, 2A and 2B). As shown in FIG. 3B, the PCB core material 320a can be disposed on a carrier material 330, which can be a carrier tape, a prepreg material layer, and/or a metal layer. The exact structure of the carrier material 330 will depend on the particular implementation. As shown in FIG. 3B, the carrier material 330 defines respective bottom surfaces of the cavity 321a and the cavity 321b. As also shown in FIG. 3B, a module substrate 312a can be disposed in the cavity 321a, and a module substrate 312b can be disposed in the cavity 321b, such as on the carrier material 330.

Referring now to FIG. 3C, semiconductor die, such as semiconductor die 316 and 317 can be coupled (sintered, soldered, etc.) with the module substrate 312a and the module substrate 312b. As shown in FIG. 3D, after coupling the semiconductor die with the module substrates, a prepreg layer 320b1 can be applied, and a resin flow process performed to embed the module substrate 312a in the cavity 321a, and to embed the module substrate 312b in the cavity 321b (at least partially embedded at this point in the process).

As shown in FIG. 3E, after applying the prepreg layer 320b1, as shown in FIG. 3D, an additional prepreg material layer 320b2 can be applied, along with a metal foil layer 340a, and a resin flow process can be performed to laminate the prepreg material layer 320b2 to the prepreg material layer 320b1 and/or to the semiconductor die (e.g., semiconductor die 316 and 317) coupled with the module substrates 312a and 312b. As shown in FIG. 3F, via openings 350 can then be formed through the prepreg material layer 320b2 and the metal foil layer 340a (e.g., using drilling, etching, laser ablation, etc.).

As shown in FIG. 3G, metallization can then be formed, along with additional prepreg material, such as included in a layer 340b. Forming metallization can include plating, deposition, sputtering, etc. The metallization, e.g., after structuring, can form electrical contacts and wire traces to the module substrates and/or the semiconductor die to define a circuit (e.g., a half-bridge circuit) of the in process semiconductor device assembly. While not specifically shown, the process of FIGS. 3A through 3G can also include forming additional via openings (e.g., through the layer 340b), additional metallization, and additional prepreg material, e.g., to define additional electrical connections (e.g., to the metal foil layer 340a0, as well as to define external electrical contact surfaces for the associated semiconductor device module (e.g., for busbar connections in a corresponding electrical system, such as for DC+, DC− and output terminals). Further, the process of FIGS. 3A and 3G can also include forming signal pin sockets, e.g., plated holes or plated through holes in the prepreg material and/or metallization layers.

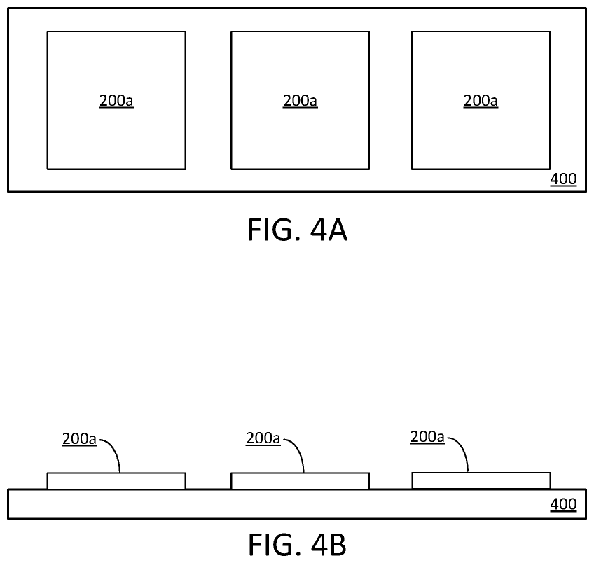

FIGS. 4A and 4B are diagrams schematically illustrating an example of semiconductor device assemblies coupled with a heatsink or cooling jacket. In this example, a plurality of the semiconductor device assembly 200a can be coupled with a heat dissipation device 400, such as a heat sink or a fluidic cooling jacket. FIG. 4A is a top-down view of the three of the semiconductor device assembly 200a coupled with a surface of the heat dissipation device 400. FIG. 4B is a side view arrangement of FIG. 4A.

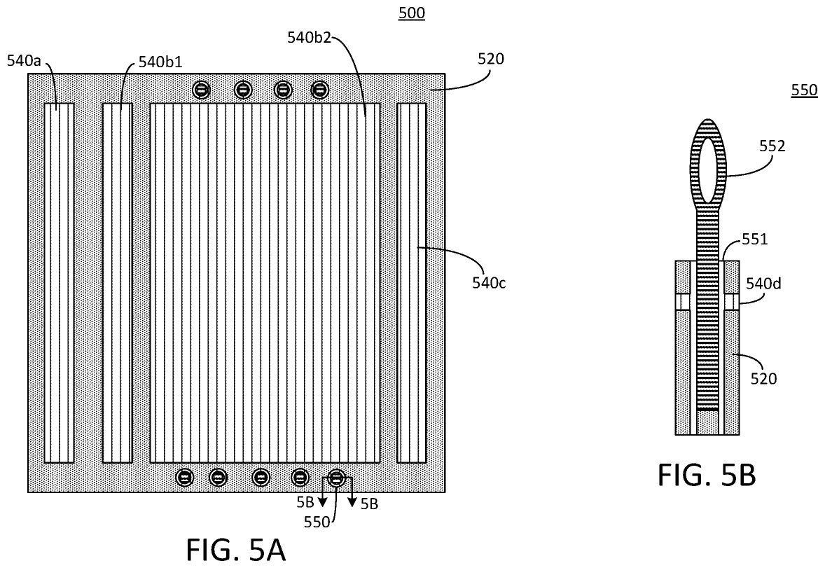

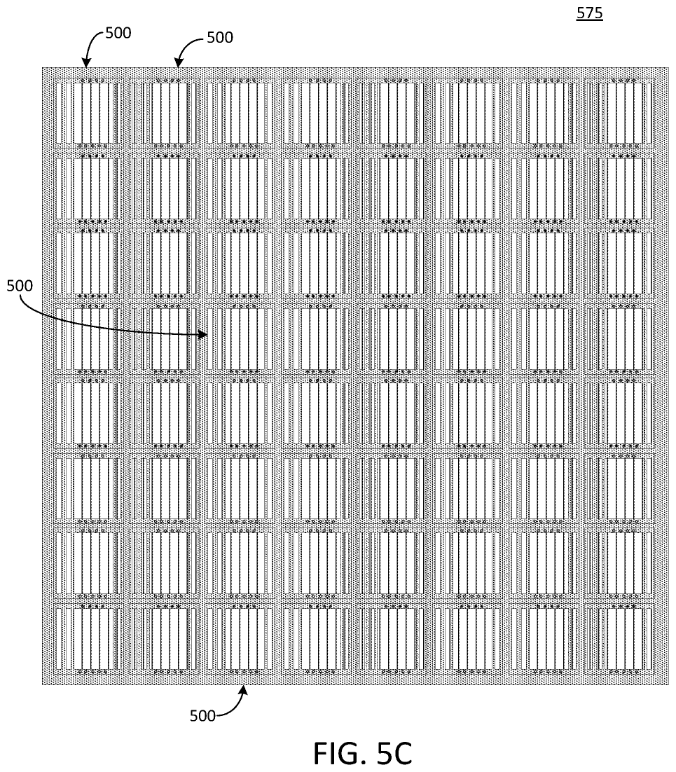

FIG. 5A is a diagram illustrating an example of another semiconductor device assembly 500 that includes embedded semiconductor device modules, such as in the semiconductor device assembly 200a, and/or the semiconductor device assembly 200b. In this example, only the external structure of the semiconductor device assembly 500 is shown, with a cross-sectional view of a signal pin structure 550 of the semiconductor device assembly 500 being illustrated in FIG. 5B. As shown in FIG. 5A, which can also implement a half-bridge circuit, the semiconductor device assembly 500 includes PCB material 520 (e.g., a laminated prepreg material layer) and metal exposed through the PCB material 520. For instance, exposed portions of the metal layer can be respective portions of a surface of a patterned metal layer that is formed using a PCB lamination process, such as in the process of FIGS. 3A through 3G, or in the method of FIG. 7.

In this example, the surface of the metal layer (e.g., a patterned metal layer) exposed through the PCB material 520 includes a DC+ terminal 540a of the half-bridge circuit of the semiconductor device assembly 500, a DC− terminal 540b1 of the half-bridge circuit, a DC-terminal 540b2 of the half-bridge circuit, and an output terminal 540c (switching node) of the half-bridge circuit. In this example, internal metal layers can be used to route the DC+ terminal 540a and the DC− terminals (including the terminal 540b1 and the terminal 540b2), such that respective portions of those internal metal layer are routed parallel to one another, which can reduce a stray inductance of the semiconductor device assembly 500 associated with the DC+ terminal and the DC− terminals.

As also shown in FIG. 5A, the semiconductor device assembly 500 includes a plurality of signal pin structures 550 that can be coupled, via respective PCB wire traces, between the plurality of signal pin structures 550 and the semiconductor die of the half-bridge circuit of the semiconductor device assembly 500.

FIG. 5B is a diagram illustrating a side, cross-sectional view of a signal pin structure of the plurality of signal pin structures 550 of the semiconductor device assembly 500 along the section line 5B-5B in FIG. 5A. As shown in FIG. 5B, in this example, the signal pin structure 550 includes a metal-plated through hole 551 defined in the PCB material 520. The metal-plated through hole 551 can be referred to as a socket, a signal pin socket, a signal pin holder, etc. In some implementations, a signal pin structure can include a metal-plated hole that terminates within an associated assembly, rather than extending entirely through the assembly. For instance, in some implementations, such a plated signal pin socket can terminate at a surface of a module substrate included in a semiconductor device assembly, such as a DBC substrate or an AMB substrate of the semiconductor device assembly 500.

As also shown in FIG. 5B, the signal pin structure 550 includes a PCB wire trace 540d, which can be used to electrically couple a signal pin 552 of the signal pin structure 550 with a semiconductor die included in the semiconductor device assembly 500. For instance, the signal pin 552 can be soldered in the metal-plated through hole 551, which can be electrically coupled with the PCB wire trace 540d. That is, the metal-plated through hole 551 and the PCB wire trace 540d can be electrically continuous. In some implementations, the signal pin can be press-fit (friction-fit) in the metal-plated through hole 551.

FIG. 5C is a diagram illustrating an example panel 575 including a plurality of the semiconductor device assemblies 500 of FIG. 5A. In this example, the panel 575 includes an eight-by-eight array of the semiconductor device assemblies 500. Accordingly, the panel 575 includes sixty-four of the semiconductor device assemblies 500. As shown in FIG. 5C, the sixty-four semiconductor device assemblies 500 can be produced using a single panel of PCB core material, where respective cavities can be formed in the panel of PCB material for each of the individual semiconductor device assemblies 500. Each individual semiconductor device assembly 500 (or groups of multiple semiconductor device assemblies 500) can be singulated from (separated from, removed from, etc.) the panel 575 using laser cutting, saw cutting, water jet cutting, etc.

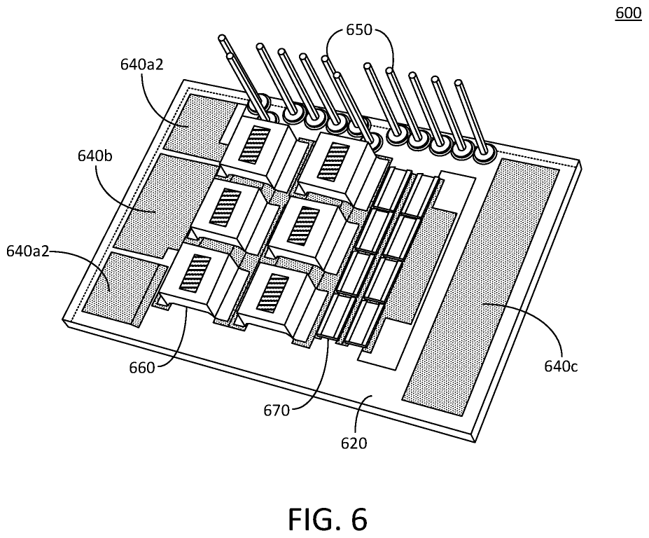

FIG. 6 is diagram illustrating an example of yet another semiconductor device assembly 600. In this example, the semiconductor device assembly 600 includes embedded semiconductor device modules, such as in the semiconductor device assembly 200a, and/or the semiconductor device assembly 200b. In this example, as with the example of FIGS. 5A-5C, only the external structure of the semiconductor device assembly 600 is shown. As shown in FIG. 6, which can also implement a half-bridge circuit, the semiconductor device assembly 600 includes PCB material 620 (e.g., a laminated prepreg material layer) and metal exposed through the PCB material 620 (e.g. a metal layer laminated in conjunction with prepreg material of the PCB material 620). For instance, exposed portions of the metal layer can be respective portions of a surface of a patterned metal layer that is formed using a PCB material lamination process, such as in the process of FIGS. 3A through 3G, or in the method of FIG. 7.

In this example, the surface of the metal layer (e.g., a patterned metal layer) exposed through the PCB material 620 includes a DC+ terminal 640al of the half-bridge circuit of the semiconductor device assembly 600, a DC+ terminal 640a2 of the half-bridge circuit, a DC− terminal 640b of the half-bridge circuit, and an output terminal 640c (switching node) of the half-bridge circuit. In this example, as with the semiconductor device assembly 500 of FIG. 5A, internal metal layers can be used to route the DC+ terminals (including the terminals 640al and 640a2) and the DC− terminal 640b, such that respective portions of those internal metal layer are routed parallel to one another, which can reduce a stray inductance of the semiconductor device assembly 600 associated with the DC+ terminals and the DC− terminal. The semiconductor device assembly 600 also includes a plurality of signal pins 650 that can be coupled with the circuit (e.g., half-bridge circuit) implemented by the semiconductor device assembly 600, such as using printed circuit wire traces.

As shown in FIG. 6. The semiconductor device assembly 600 includes a plurality of surface mounted capacitors 660 and plurality of surface mounted resistors 670. In this example, laminated prepreg layers and patterned metal layers can be used to form PCB wire traces to couple the plurality of surface mounted capacitors 660 and the plurality of surface mounted resistors 670 with the half-bridge circuit of the semiconductor device assembly 600. Such an approach may not be achievable using prior implementations (e.g., transfer molded modules including a leadframe) due to associated manufacturing constraints.

FIG. 7 is a flowchart illustrating an example method 700 for producing a semiconductor device assembly. For instance, the method 700 can be used to produce the semiconductor device assembly 200a of FIG. 2A, the semiconductor device assembly 200b of FIG. 2B, as well as other assemblies with semiconductor device modules embedded in PCB materials. In this example, the method 700 (e.g., block 710 to block 750) generally corresponds with the process illustrated by FIGS. 3A through 3G. The method 700 further includes operations (e.g., block 760 to block 780) that can be used to produce implementations of the arrangement shown in FIGS. 4A and 4B, e.g., a plurality of devices assemblies, such as the semiconductor device assembly 200a coupled with the heat dissipation device 400, e.g., a heat sink or fluidic cooling jacket.

As shown in FIG. 7, the method 700 includes, at block 710, disposing a module substrate (e.g., a DBC substrate, an AMB substrate, etc.) in a cavity defined in a panel of PCB core material. For instance, the cavity may be an opening that is defined through the panel of PCB core material. In some implementations, the cavity can be formed in a separate process operation than the operations of the method 700. For instance, the cavity can be formed by laser cutting, saw cutting, etching, machining, etc. In other implementations, the cavity can be defined when producing the panel of PCB core material.

In some implementations, the panel of PCB core material can be disposed on a back side layer, such as a carrier tape, a layer of prepreg material (cured or uncured), a metal layer, etc. In such implementations, the back side layer can define a bottom cavity surface. For instance, disposing the module substrate in the cavity at block 710 can include disposing the module substrate on the bottom cavity surface (e.g., on a surface of such a back side layer).

At block 720, the method 700 includes attaching (coupling, etc.) one or more semiconductor die to the module substrate. In some implementations, the operation at block 720 can include sintering, soldering, eutectic scrubbing, etc. to attach the semiconductor die to a patterned metal layer (e.g., copper layer, or other metal layer) of the module substrate. In some implementations, the method 700 can be performed using multiple module substrates that, at block 710, are disposed in respective cavities in the corresponding panel of PCB core material.

At block 730, the method 700 includes laminating the assembly with prepreg material and/or copper foil (copper sheets), to embed the semiconductor device module and the one more associated semiconductor die in PCB materials (e.g., embed in the cavity and the laminated layers applied at block 730). At block 740, via openings are formed through the prepreg layer and/or the copper foil layer of block 730. In some implementations, the via openings are formed through the layer(s) of block 730 to facilitate forming electrical contacts with the module substrate and the one more semiconductor die, such as in the example implementations, described herein.

At block 750, the method includes forming metallization layers to electrically interconnect the elements of the assembly being produced, such as filling the via openings of block 740, forming printed circuit wire traces, etc. The operation(s) at block 750 can include metal plating, metal deposition (e.g., sputtering, etc.), structuring metal traces (e.g., using laser ablation, etching, etc.), and/or forming additional prepreg laminated layers and/or metal layers (e.g., copper foil or sheet, plated metal, etc.) to interconnect a circuit implemented by the produced assembly.

At block 760, the PCB materials (PCB core material and/or prepreg PCB material) can be cut (laser cut, precision sawn, etc.) to singulate (separate, remove, etc.) a device assembly including one or more embedded semiconductor modules from a panel of embedded semiconductor modules (e.g., the panel 575 of FIG. 5C). At block 770, the method 700 includes attaching and/or inserting signal pins of the semiconductor device module. For instance at block 770, signal pins can be soldered in plated through holes of the semiconductor device assembly, and/or can be press-fit inserted into the semiconductor device assembly. At block 780, the embedded semiconductor device module (or modules) can be coupled with a heatsink or fluidic cooling jacket, such as in the example of FIGS. 4A and 4B. The operation at block 780 can include sintering, soldering, brazing, etc.

In a general aspect, an assembly includes a panel of organic substrate core material having a cavity defined therein, a module substrate disposed in the cavity, and a semiconductor die disposed on the module substrate. The assembly also includes a layer of prepreg organic substrate material, and a metal layer. The module substrate and the semiconductor die are embedded in the cavity by the layer of prepreg organic substrate material and the metal layer. The metal layer is electrically coupled with at least one of the semiconductor die or the module substrate.

Implementations can include one or more of the following features or aspects, alone or in combination. For example, the layer of prepreg organic substrate material can include a plurality of layers of prepreg organic substrate material.

The cavity can be an opening defined through the panel of organic substrate core material.

The module substrate can be one of a direct-bonded copper (DBC) substrate, or an active metal-brazed (AMB) substrate.

The layer of prepreg organic substrate material can be a first layer of prepreg organic substrate material The metal layer can be a first metal layer. The assembly can include a second layer of prepreg organic substrate material, and a second metal layer. The module substrate and the semiconductor die can be further embedded in the cavity by the second layer of prepreg organic substrate material and the second metal layer. The second metal layer can be electrically coupled to the first metal layer. A surface of the second metal layer can be exposed through the second layer of prepreg organic substrate material.

The cavity can be a first cavity. The panel of organic substrate core material can include a second cavity. The module substrate can be a first module substrate, and the semiconductor die can be a first semiconductor die. The assembly can include a second module substrate disposed in the second cavity, and a second semiconductor die disposed on the second module substrate. The second module substrate and the second semiconductor die can be embedded in the second cavity by the layer of prepreg organic substrate material and the metal layer. The metal layer can electrically couple the first semiconductor die with the second module substrate.

The assembly can include a metal-plated socket defined in the layer of prepreg organic substrate material, and a signal pin disposed in the metal-plated socket. The signal pin can be electrically coupled with the semiconductor die via the metal layer.

The metal layer can be a patterned metal layer.

The metal layer can be electrically coupled with at least one of the semiconductor die or the module substrate by at least one conductive via defined in the layer of prepreg organic substrate material.

The layer of prepreg material and the metal layer can be disposed on a first side of the panel of organic substrate core material. The metal layer can be a first metal layer. The assembly can include a second metal layer disposed on a second side of the panel of organic substrate core material, the second side being opposite the first side, the second metal layer being in contact with the module substrate.

The layer of prepreg material and the metal layer can be disposed on a first side of the panel of organic substrate core material. The layer of prepreg organic substrate material can be a first layer of prepreg organic substrate core material. The metal layer can be a first metal layer. The assembly can include a second layer of prepreg organic substrate material disposed on a second side of the panel of organic substrate material, he second side being opposite the first side. The assembly can include a second metal layer disposed on the second layer of prepreg organic substrate material. The second metal layer can be thermally coupled with the module substrate by a plurality of metals via defined in the second layer of prepreg organic substrate material.

In another general aspect, an assembly includes a panel of organic substrate core material having a first cavity and a second cavity defined therein, a first module substrate disposed in the first cavity, a first semiconductor die disposed on the first module substrate, a second module substrate disposed in the second cavity, a second semiconductor die disposed on the second module substrate, a first layer of prepreg organic substrate material, a first metal layer, a second layer of prepreg organic substrate material, and a second metal layer. The first module substrate, the first semiconductor die, the second module substrate and the second semiconductor die are embedded, respectively, in the first cavity and the second cavity by the first layer of prepreg organic substrate material, the first metal layer, the second layer of prepreg organic substrate material, and the second metal layer.

Implementations can include one or more of the following features or aspects, alone or in combination. For example, the first metal layer can be a first patterned metal layer that is electrically coupled with at least one of the first module substrate; the first semiconductor die; the second module substrate; or the second semiconductor die. The second metal layer can be a second patterned metal layer that is electrically coupled with the first patterned metal layer. The second metal layer can have a surface exposed through the second layer of prepreg organic substrate material.

The first layer of prepreg organic substrate material can include a plurality of layers of prepreg organic substrate material.

The first layer of prepreg material, the first metal layer, the second layer of prepreg material, the second metal layer can be disposed on a first side of the panel of organic substrate core material. The assembly can include a third metal layer disposed on a second side of the panel of organic substrate core material, the second side being opposite the first side. The second metal layer can be in contact with the first module substrate and the second module substrate.

In another general aspect, a method for producing a semiconductor device assembly includes disposing a module substrate in a cavity defined in a panel of organic substrate core material, and coupling a semiconductor die with the module substrate. The method further includes embedding the module substrate and the semiconductor die by laminating, with a layer of prepreg organic substrate material, the panel of organic substrate core material, the module substrate and the semiconductor die. The method also includes forming a plurality of via openings through the layer of prepreg organic substrate material, and forming a patterned metal layer on the layer of prepreg organic substrate material. The patterned metal layer electrically contacts the module substrate and semiconductor die through the plurality of via openings. The layer of prepreg organic substrate material can include a plurality of layers of prepreg organic substrate material.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, silicon (Si), gallium arsenide (GaAs), gallium nitride (GaN), silicon carbide (SiC) and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An assembly comprising:
a panel of organic substrate core material having a cavity defined therein;
a module substrate disposed in the cavity;
a semiconductor die disposed on the module substrate;
a layer of prepreg organic substrate material; and
a metal layer,
the module substrate and the semiconductor die being embedded in the cavity by the layer of prepreg organic substrate material and the metal layer, and
the metal layer being electrically coupled with at least one of the semiconductor die or the module substrate.

2. The assembly of claim 1, wherein the layer of prepreg organic substrate material includes a plurality of layers of prepreg organic substrate material.

3. The assembly of claim 1, wherein the cavity includes an opening defined through the panel of organic substrate core material.

4. The assembly of claim 1, wherein the module substrate is one of:
a direct-bonded copper (DBC) substrate; or
an active metal-brazed (AMB) substrate.

5. The assembly of claim 1, wherein:
the layer of prepreg organic substrate material is a first layer of prepreg organic substrate material; and
the metal layer is a first metal layer,
the assembly further comprising:
a second layer of prepreg organic substrate material;
and a second metal layer,
the module substrate and the semiconductor die being further embedded in the cavity by the second layer of prepreg organic substrate material and the second metal layer.

6. The assembly of claim 5, wherein the second metal layer is electrically coupled to the first metal layer.

7. The assembly of claim 5, wherein a surface of the second metal layer is exposed through the second layer of prepreg organic substrate material.

8. The assembly of claim 1, wherein:
the cavity is a first cavity, the panel of organic substrate core material including a second cavity;
the module substrate is a first module substrate; and
the semiconductor die is a first semiconductor die,
the assembly further comprising:
a second module substrate disposed in the second cavity; and
a second semiconductor die disposed on the second module substrate;
the second module substrate and the second semiconductor die being embedded in the second cavity by the layer of prepreg organic substrate material and the metal layer.

9. The assembly of claim 8, wherein the metal layer electrically couples the first semiconductor die with the second module substrate.

10. The assembly of claim 1, further comprising:
a metal-plated socket defined in the layer of prepreg organic substrate material; and
a signal pin disposed in the metal-plated socket,
the signal pin being electrically coupled with the semiconductor die via the metal layer.

11. The assembly of claim 1, wherein the metal layer is a patterned metal layer.

12. The assembly of claim 1, wherein the metal layer is electrically coupled with at least one of the semiconductor die or the module substrate by at least one conductive via defined in the layer of prepreg organic substrate material.

13. The assembly of claim 1, wherein the layer of prepreg material and the metal layer are disposed on a first side of the panel of organic substrate core material, the metal layer being a first metal layer,
the assembly further comprising a second metal layer disposed on a second side of the panel of organic substrate core material, the second side being opposite the first side, the second metal layer being in contact with the module substrate.

14. The assembly of claim 1, wherein the layer of prepreg material and the metal layer are disposed on a first side of the panel of organic substrate core material, the layer of prepreg organic substrate material being a first layer of prepreg organic substrate core material, the metal layer being a first metal layer,
the assembly further comprising:
a second layer of prepreg organic substrate material disposed on a second side of the panel of organic substrate material, the second side being opposite the first side; and
a second metal layer disposed on the second layer of prepreg organic substrate material, the second metal layer being thermally coupled with the module substrate by a plurality of metals via defined in the second layer of prepreg organic substrate material.

15. An assembly comprising:
a panel of organic substrate core material having a first cavity and a second cavity defined therein;
a first module substrate disposed in the first cavity;
a first semiconductor die disposed on the first module substrate;
a second module substrate disposed in the second cavity;
a second semiconductor die disposed on the second module substrate;
a first layer of prepreg organic substrate material;
a first metal layer;
a second layer of prepreg organic substrate material; and
a second metal layer;
the first module substrate, the first semiconductor die, the second module substrate and the second semiconductor die being embedded, respectively, in the first cavity and the second cavity by the first layer of prepreg organic substrate material, the first metal layer, the second layer of prepreg organic substrate material, and the second metal layer.

16. The assembly of claim 15, wherein:
the first metal layer is a first patterned metal layer that is electrically coupled with at least one of:
the first module substrate;
the first semiconductor die;
the second module substrate; or
the second semiconductor die; and
the second metal layer is a second patterned metal layer that:
is electrically coupled with the first patterned metal layer; and
has a surface exposed through the second layer of prepreg organic substrate material.

17. The assembly of claim 15, wherein the first layer of prepreg organic substrate material includes a plurality of layers of prepreg organic substrate material.

18. The assembly of claim 15, wherein the first layer of prepreg material, the first metal layer, the second layer of prepreg material, the second metal layer are disposed on a first side of the panel of organic substrate core material,
the assembly further comprising a third metal layer disposed on a second side of the panel of organic substrate core material, the second side being opposite the first side, the second metal layer being in contact with the first module substrate and the second module substrate.

19. A method for producing a semiconductor device assembly, the method comprising:
disposing a module substrate in a cavity defined in a panel of organic substrate core material;
coupling a semiconductor die with the module substrate;
embedding the module substrate and the semiconductor die by laminating, with a layer of prepreg organic substrate material, the panel of organic substrate core material, the module substrate and the semiconductor die;
forming a plurality of via openings through the layer of prepreg organic substrate material; and
forming a patterned metal layer on the layer of prepreg organic substrate material, the patterned metal layer electrically contacting the module substrate and semiconductor die through the plurality of via openings.

20. The method of claim 19, wherein the layer of prepreg organic substrate material includes a plurality of layers of prepreg organic substrate material.
